(19) United States
(12) Patent Application Publication
(10) Pub. No.: US 2019/0006209 A1
(43) Pub. Date: Jan. 3, 2019

(54) DEVICE AND METHOD FOR HOLDING, ROTATING, AS WELL AS HEATING AND/OR COOLING A SUBSTRATE

(71) Applicant: EV Group E. Thallner GmbH, St. Florian am Inn (AT)

(72) Inventors: Thomas Wieser, Kirchdorf (DE); Michael Tischler, Suben (AT)

(73) Assignee: EV Group E. Thallner GmbH, St. Florian am Inn (AT)

(21) Appl. No.: 16/066,340

(22) PCT Filed: Jan. 24, 2017
(86) PCT No.: PCT/EP2017/051430

§ 371 Date: Jun. 27, 2018

(30) Foreign Application Priority Data
Feb. 24, 2016 (DE) 10 2016 103 270.0

(51) Int. Cl. H01L 21/67; H05B 6/10; F25B 21/02; H01L 21/687

(52) U.S. Cl. CPC H01L 21/67103; H01L 21/68792; F25B 21/02; H05B 6/107

(57) ABSTRACT

A device and a method for holding, rotating, heating and/or cooling a substrate. The device comprises a rotor, having: at least one secondary winding, a substrate holder with a substrate holder surface and fixing elements for fixing the substrate, a rotary shaft for rotating the substrate holder around a rotary axis, at least one electric heater for heating and/or a cooler for cooling the substrate holder surface; and a stator, having: at least one primary winding, a ring-shaped base, wherein the rotary shaft of the rotor is arranged at least partially inside the base; and wherein a current and/or a voltage is induced in the at least one secondary winding by the at least one primary winding, the induced current and/or voltage used to power the at least one heater and/or cooler so that the substrate holder surface is heated and/or cooled.

The invention relates to a device and a method for holding, rotating as well as heating and/or cooling a substrate in accordance with the subordinate patent claims.

In the industry numerous types of sample holder are used to fix substrates, in particular wafers. These sample holders are required to perform various physical tasks. On the one hand the sample holders serve to fix the substrate. The fixing is often achieved by mechanical clamping, vacuum tracks, electrostatic charges, electrical or magnetic fields, or adhesive surfaces.

Very many sample holders also perform secondary tasks such as cooling or heating a substrate. Heated sample holders in particular are very common and are present in many different embodiments.

Sample holders are often tailored to the equipment in which they are used. Sample holders for spin coating equipment which rotate at several thousand rotations per minute, must be constructed in a highly symmetrical, light and flexible manner. They must, in particular, be correctly weighted. This type of sample holder is often required to have secondary functionalities such as heating.

The temperature of a heated sample holder is controlled directly via a heating element, which must be activated by an appropriately supplied current. The biggest problem arises in the transmission of the current to the rotating sample holder. The transmission of current between two rotating parts is normally effected via sliding contacts. Sliding contacts have a number of disadvantages. Firstly, there is a high level of wear between the sliding contact and the collector. Secondly, this type of contact can lead to spark discharge. Many fluids, especially solvents, are relatively highly flammable and have a relatively high vapour pressure. It must therefore always be assumed that there may be flammable gases around a heated sample holder, which may lead to an explosion. Centrifuge units are regularly used to coat or to clean substrate surfaces. For this purpose chemicals are used which may be flammable. If these fluids also have high vapour pressures, even a small spark can lead to an explosion or a fire.

It is therefore the requirement of the present invention to provide a device and a method for holding, rotating as well as heating and/or cooling a substrate, which do not have the disadvantages of the state of the art and which are in particular as wear-free as possible and offer as high as possible a level of operational safety.

The embodiments of the invention described below are suitable for use as a coater or a cleaner. In the former case they are also called spin coaters.

These requirements/tasks are met by the subject matter of the subordinate patent claims. Further advantageous developments of the invention are set out in the sub-claims.

Any combinations of at least two of the characteristics set out in the description, the claims and/or the drawings also fall within the scope of the invention. Where value ranges are indicated, all values falling within the said limits shall be deemed disclosed and claimed in any random combination.

According to the invention provision is made for a device for holding, rotating, as well as heating and/or cooling a substrate, in particular a wafer, with:

1) a rotor, having:
a) at least one secondary winding;
b) a substrate holder with a substrate holder surface and fixing elements for fixing the substrate;
c) a rotary shaft for rotating the substrate holder around a rotary axis;
d) at least one electric heater for heating and/or a cooler for cooling the substrate holder surface;
e) optionally, an electronic control system to control a current and/or a voltage in the at least one primary winding;

2) a stator, having:
a) at least one primary winding;
b) optionally, an electronic control system to control a current and/or a voltage in the at least one primary winding;
c) a ring-shaped base, wherein the rotary shaft of the rotor is arranged at least partially inside the base;
   wherein the device is designed such that a current and/or a voltage can be induced in the at least one secondary winding by the at least one primary winding, wherein the current or voltage induced in the at least one secondary winding can be used to operate the at least one heater and/or cooler such that the substrate holder surface can be heated and/or cooled.

Devices for cooling the substrate are generally called coolers. Peltier elements in particular may be used for cooling the substrate. According to the invention, heaters and/or coolers can be built into the inventive sample holder.

A preferred embodiment provides that the at least one primary winding is arranged on a surface of the base. This has the advantage of achieving a particularly good energy transfer.

Another preferred embodiment provides that the at least one primary winding is arranged inside the base. This has the advantage that a particularly space-saving design is possible.

Another preferred embodiment provides that the at least one primary winding and the at least one secondary winding are designed as flat coils, preferably as spiral coils, and even more preferably as Archimedean spiral coils. This has the advantage that a particularly space saving design is possible.

Another preferred embodiment provides that the at least one primary winding and the at least one secondary winding are arranged parallel to one another. This has the advantage of achieving a particularly good energy transfer.

Another preferred embodiment provides that the at least one primary winding and the at least one secondary winding are arranged in and/or parallel to a plane wherein the plane is at right angles to the rotary axis. This has the advantages that a particularly space-saving realisation and a particularly good energy transfer are possible.

Another preferred embodiment provides that the at least one primary winding is arranged on a base surface of the base facing the substrate holder. This has the advantage of achieving a particularly good energy transfer.

Another preferred embodiment provides that the at least one secondary winding is arranged on a reverse side of the substrate holder facing the base. This has the advantage of achieving a particularly good energy transfer.

Another preferred embodiment provides that the at least one primary winding and the at least one secondary winding are designed as cylinder coils. This has the advantage of achieving a particularly good energy transfer.

Another preferred embodiment provides that the at least one primary winding and the at least one secondary winding are arranged concentrically in relation to the rotary axis. This has the advantage of achieving a particularly good energy transfer.

Another preferred embodiment provides that the at least one primary winding is arranged on an inner base surface facing the rotary shaft and the at least one secondary winding is arranged on a shaft surface of the rotary shaft facing the inner base surface. This has the advantage of achieving a particularly good energy transfer.

Another preferred embodiment provides that the at least one primary winding and the at least one secondary winding are arranged acentrically in relation to the rotary axis. This has the advantage of achieving a particularly good energy transfer.

Another preferred embodiment provides that at least two primary windings are arranged inside the base and at least two secondary windings are arranged inside the rotary shaft. This has the advantage of achieving a particularly good energy transfer.

Another preferred embodiment provides that the at least two primary windings and the at least two secondary windings are arranged at the same angular distance around the rotary axis. This has the advantage of achieving a particularly good energy transfer along with the most space-saving design possible.

Another preferred embodiment provides that the device has a measuring device for measuring the temperature of the heater, the substrate holder, the substrate holder surface and/or the substrate, as well as a device for transmitting the temperature measurements for the heater, the substrate holder, the substrate holder surface and/or the substrate from the rotor to the stator, preferably via the inductive coupling between the at least one primary winding and the at least one secondary winding. This has the advantage that the temperature can be particularly well controlled.

Another preferred embodiment provides that the rotor has an identification chip, in particular an RFID chip, for unequivocal and in particular fully automated identification of the rotor, wherein the identification chip is preferably located on the rim of the rotary shaft. This has the advantage that the rotor can be exchanged particularly easily.

Another preferred embodiment provides that the device is provided with a flushing agent for flushing the rotor using a gas flow. This has the advantage that the device is particularly safe to operate.

Furthermore, the invention provides a method for holding, rotating as well as heating and/or cooling a substrate, in particular a wafer, with the following steps, in particular with a device with the following characteristics:
holding and rotating the substrate using a rotor, comprising a substrate holder with a substrate holder surface and fixing elements for fixing the substrate, wherein the substrate holder with the substrate is turned around a rotary axis by a rotary shaft;
inducing a current, in particular by virtue of rotating the rotor, in at least one secondary winding of the rotor by at least one current-carrying primary winding of a stator;
wherein at least one heater and/or cooler is operated by the current induced in the at least one secondary winding such that the substrate holder surface and thereby the substrate are heated and/or cooled.

A preferred embodiment provides that the rotor is flushed by a gas flow, in particular an inert gas flow, wherein preferably externally attached electric components, in particular a primary-side capacitor component and a secondary-side capacitor component, are flushed, wherein an overpressure is built up preferably between the rotor and the stator, which is greater than an ambient pressure. This has the advantage of making the operation of the device particularly safe.

In the following text ‘stator-side’ is also described as ‘primary-side’, and ‘rotor-side’ as ‘secondary-side’. In the following text a ‘winding’ is also described as a ‘coil’. In the following text the ‘substrate holder’ is also described as ‘sample holder’.

The core of the invention, in particular, consists in the transmission of the electrical power/the voltage and/or the current from a stator to a rotor by electromagnetic induction. Further, it discloses a number of possibilities for contact-free transmission of measurement signals.

The embodiment of the invention separates the mechanical components from the electrical components. In particular, there is no longer a need for sliding contacts, which in an oxidizing atmosphere in particular, pose a significant safety risk from sparking.

In particular the invention describes a method and a system for electromagnetically decoupled transmission of current by electromagnetic induction as well as electromagnetically decoupled temperature measurement-taking by inductive, capacitive or electromagnetic methods, and the control made possible by those processes.

### Electromagnetic Induction

At the basis of the invention is the fundamental principle of an inductive coupling for the transmission of power, voltage/current to the heating elements. The inductive coupling can also be understood as a transformer. The transformer is made up of a primary side and a secondary side. The primary and secondary sides each have at least one conductor loop, in particular a coil. As the text develops, ‘conductor loop’ and ‘coil’ will be used as synonyms. The arrangement and number of coils may vary according to the embodiment of the invention.

In particular, the coils have exactly 1 winding, preferably more than 5 windings, even more preferably more than 10 windings, most preferably more than 100 windings, most preferably of all, more than 1000 windings. In especially preferred embodiments coils with between 5 and 100 windings are used.

The primary side is a part of the stator. The secondary side is a part of the rotor. The stator is made up of the amount of all static mechanical components, which are static. The rotor is made up of the amount of mechanical parts, which rotate as a whole. The rotor and stator are completely electromagnetically decoupled from one another. By electromagnetic decoupling it is understood that the power transmission from a first mechanical part, in particular the stator, to the second mechanical part, in particular the rotor, is not effected via power lines and/or sliding contacts, but rather via electromagnetic induction. Thus, in contrast to the state of the art, power transmission is effected exclusively by electromagnetic induction.

According to Faraday's law of induction, a voltage is always produced by a conductor loop if the magnetic flux in the conductor loop changes over time. This can be more clearly explained in that the number of magnetic field lines per unit area, i.e. the density of field lines, running through the conductor loop changes over time. This change can be produced by different physical effects.

It is possible to change the field line density by a periodic variation of the current, which produces the magnetic field. Of sole relevance in this process is the fact that the strength of the current, which correlates with the strength of the magnetic field, is changed. For this reason it is equally possible to use a pulsed or oscillating direct current or an alternating current. An alternating current is identifiable by the changing direction of the current and therefore by a repeated reversal of polarity in the magnetic field, whilst a pulsed or oscillating direct current never changes its algebraic sign although the field line density and therefore the magnetic flux still change.

A further alternative is represented by the purely mechanical relative motion between the magnetic field produced and the decreasing conductor loop. Here, the conductor loop passes through areas with high and low field line densities. This relative motion also results in a temporal variation of the magnetic flux. Similar considerations apply to the approach taken in relation, not to the temporal variation of the magnetic flux, but to the temporal variation of the magnetic induction, or magnetic field strength. The embodiments of the invention are concerned, in relation to the relative motion, exclusively with a rotational movement of the rotor relative to the stator. In this case it is significant that, during a rotational movement, the secondary coil passes through an asymmetrical magnetic field of the primary coil.

In a further alternative, the two effects described above are combined with one another.

In an exemplary embodiment of the invention, transmission of electrical power is achieved by the application of an oscillating direct current, but preferably through an applied alternating current, on the primary side. Flat coils are used on the primary and secondary sides. Since the magnetic field applied on the primary side is not radially symmetrical around an axis Ap of the primary side flat coil, a voltage can also be produced on the secondary side purely by rotation without applying an oscillating direct current or an alternating current. The flat coils are constructed in particular as spirals, more preferably as Archimedean spirals. The flat coil on the primary side can be mounted in or on the stator. The flat coil on the secondary side can be mounted in or on the rotor, in particular in the sample holder.

In another exemplary embodiment of the invention, transmission of electrical power is achieved by the application of an oscillating direct current, but preferably by an applied alternating current, on a primary-side coil.

Since, in this embodiment of the invention, the axis Ap of the primary coil and the axis As of the secondary coil coincide with one another, and the resulting magnetic field on the primary side is radially aligned around the coil axis Ap, the variation of the magnetic flux by the secondary coil can never be achieved by purely a relative motion, but exclusively by an oscillating direct current, however preferably by an applied alternating current.

In another exemplary embodiment of the invention, transmission of electrical power is achieved by two coils mounted asymmetrically to one another and rotating towards one another. Although the magnetic field produced on the primary side is symmetrical around the axis Ap, the axes Ap and As do not coincide with one another. Thus where there is a relative motion between stator and rotor, from the perspective of the secondary coil, the magnetic field is not consistent. The secondary coil, so to speak, passes through areas with high and areas with low field line density, which in turn may lead to the induction of a secondary-side voltage. In this special embodiment, it is necessary to make sure that the number of coils on the primary side is not increased to the extent that the overlay of the magnetic fields produces a symmetrical magnetic field, which can no longer lead to the induction of a secondary-side current purely by rotational movement. Notwithstanding the above, it is still possible in this embodiment of the invention to produce a voltage in the secondary coil by applying an oscillating direct current, preferably however an applied alternating current.

The frequency of the applied alternating field is between 0 Hz and 100 kHz, preferably between 5 Hz and 75 kHz, more preferably between 10 Hz and 50 kHz, most preferably between 15 Hz and 25 kHz, most preferably of all, between 20 Hz and 20 kHz.

The voltages applied on the primary winding lie between 0 volts and 1000 volts, preferably between 5 volts and 750 volts, more preferably between 10 volts and 600 volts, most preferably between 15 volts and 500 volts, most preferably of all, between 24 volts and 400 volts.

The transferred secondary voltage and thus the transferred power during rotation of the sample holder, in particular during the acceleration phase, are preferably held constant. In the embodiments in which an asymmetrical magnetic field is built up on the primary side, the voltage induced on the secondary side will depend explicitly on the rotational speed of the sample holder. In order to hold the secondary-side voltage, and therefore the power, constant, a continuous, adjustable alternating current must in any event be applied on the primary side. The application, mentioned in embodiments of the invention, of a direct current on the primary side, thus does not allow a constant power transfer.

In conclusion, it can therefore be stated that in all of the embodiments of the invention, the application of an alternating current is always the preferred choice.

### The Sample Holder

The sample holder is preferably constructed so that it emits the heat amount produced by the heater(s) in the direction of the substrate attached to it.

The sample holder is therefore preferably constructed with an insulating underside and periphery. The insulation is mainly achieved by using materials with very low heat conductivity.

Vacuum chambers which further impede thermal flow are also preferably incorporated. The heat conductivity in the direction of the underside and the periphery is less than 1 W/m*K), preferably less than 0.05 W/(m*K), even more preferably less than 0.025 W/(m*K), most preferably less than 0.01 W/(m*K).

The sample holder is preferably constructed so that it has maximum heat conductivity in the direction of the substrate. The high heat conductivity is achieved mainly by the use of materials with high heat conductivity. The heat conductivity in the direction of the substrate lies between 0.1 W/(m*K) and 5000 W/(m*K), preferably between 1 W/(m*K) and 2500 W/(m*K), even more preferably between 10 W/(m*K) and 1000 W/(m*K), most preferably between 100 W/(m*K) and 450 W/(m*K).

The sample holder is preferably constructed so that its deviation moment around the rotary axis is nil. If the sample holder has a deviation moment other than nil, weights are used to redress the imbalance and eliminate the deviation moment.

The sample holder has fixings. The fixings serve to fix the substrate. ‘Fixings’ can mean:
mechanical fixings, in particular:
   clamps,
vacuum fixings, in particular with:
   individually controlled vacuum tracks,
   interconnected vacuum tracks.
electrical fixings, in particular:
   electrostatic fixings,
magnetic fixings
adhesive fixings, in particular:
   Gel-Pak fixings,
   fixings with adhesive, in particular controllable, surfaces.

The fixings are in particular electronically controllable. Vacuum fixings are the preferred type of fixing. A vacuum fixing primarily comprises a number of vacuum tracks which emerge from the surface of the sample holder. The vacuum tracks are preferably individually controllable. In a technically more feasible application some vacuum tracks are combined to form vacuum track segments which are individually controllable and which can therefore be evacuated or flooded. However, each vacuum segment is independent of the other vacuum segments. In this way it is possible to construct vacuum segments which are individually controllable. Vacuum segments are preferably ring-shaped. In this way a targeted, radially symmetrical fixing from inside to outside and/or detachment of the substrate from the sample holder is made possible.

In relation to the substrates, a wafer is preferable. Wafers are standardised substrates with well-defined, standardised diameters. However, the substrates can in general take any desired form. The diameters of the substrates can in general be of any size, but are mostly one of the standard diameters of 1 inch, 2 inches, 3 inches, 4 inches, 5 inches, 6 inches, 8 inches, 12 inches, 18 inches, or 25.4 mm, 50.8 mm, 76.2 mm, 100 mm, 125 mm, 150 mm, 200 mm, 300 mm, 450 mm.

It is also possible to use square substrates.

As the description progresses, ‘substrate’ is the generally used term. In particular however, the embodiments of the invention refer predominantly to wafers.

The rotational frequency is given in rounds per minute (English: ‘rounds per minute’; rpm). The sample holder can rotate at frequencies of more than 0 rpm, preferably more than 10 rpm, more preferably at more than 100 rpm, most preferably at 1000 rpm, most preferably of all, at 3000 rpm.

Acceleration is given in rpm per second (English: ‘rounds per minute per second’; rpmis). The sample holder can accelerate at more than 0 rpm/s, preferably more than 100 rpm/s, more preferably at more than 1000 rpm/s, most preferably at more than 10,000 rpm/s, most preferably of all, at more than 40,000 rpm/s.

### The Heater

The heater is a controllable and adjustable heater. The heater can be controlled in several ways.

In one embodiment of the invention the heater and the coils on the secondary side are directly connected to one another so that the current is only controlled by the size of the induced voltage, which is responsible for the heat output.

In another embodiment of the invention, there is an electronic control system in the secondary side. The current produced on the secondary side is regulated by an electronic control system. In this way a targeted influence over the current to the heater and therefore control over the heat output is possible.

In a further development of the invention, several heaters can be distributed in the sample holder. The heaters are accordingly all connected to the wires on the secondary side. Due to the use of several, in particular symmetrically arranged, heaters a temperature profile can be specifically pre-set. There are more than 1, preferably more than 3, more preferably more than 5, even more preferably more than 10, most preferably more than 25, most preferably of all, more than 100 heaters in the sample holder. The greater the number of heaters, the more complicated the electronic control system for controlling the heater will be. The heaters can be distributed symmetrically or asymmetrically in the substrate sample holder. In a preferred embodiment of the invention, the heaters are distributed in such a way that they allow the setting of a temperature gradient. Particularly preferred in this context are temperature gradients with a maximum temperature at the rim and a minimum temperature in the centre. This can be achieved by having a higher heater density at the rim. More preferable however is a heater distribution which results in a uniform heater density.

Control software and targeted control of the heaters can then be used to set and more optimally control the temperature profiles.

Heaters include:
ceramic heaters
thin-film heaters
infrared heaters

The heater can heat the sample holder, in particular the substrate, up to temperatures of between room temperature and 400° C., preferably between 50° C. and 300° C., more preferably between 100° C. and 200° C.

Power transfer according to the invention by inductive coupling can produce very high heating rates. The heating rate is between 0° C./min and 60° C./min, preferably between 0° C./min and 50° C./min, more preferably between 0° C./min and 25° C./min, more preferably between 0° C./min and 15° C./min, most preferably between 0° C./min and 10° C./min, most preferably of all, between 0° C./min and 5° C./min.

The uniformity of temperature produced by the heaters is better than 10%, preferably better than 7.5%, more preferably better than 5%, most preferably better than 2.5%, most preferably of all, better than 1%. That means, in an ideal case, that the temperature, as a function of the location fluctuates by less than 1% around the desired temperature value, provided that a uniform temperature distribution is desired. However, by using several heaters, appropriate electronics and appropriate controls, desired temperature gradients can still be produced.

The accuracy of temperature is better than 10%, preferably better than 7.5%, more preferably better than 5%, most preferably better than 2.5%, most preferably of all, better than 1%. Accuracy of temperature is understood as meaning the accuracy with which a temperature value can be set at one position. The accuracy is the degree to which the mean value diverges from the set value.

The transferred power of the embodiment of the invention is between 0 Watts and 2000 Watts, preferably between 50 Watts and 1500 Watts, more preferably between 100 Watts and 1000 Watts, most preferably between 150 Watts and 800 Watts, most preferably of all, between 200 Watts and 600 Watts. Typical outputs for heating a 200 mm wafer are in the area of 200 Watts.

### Measurement

A further task of the embodiments of the invention is to transmit measurement signals, in particular the temperature in the sample holder, more preferably the temperature in the substrate, from the rotor to the stator.

In a preferred embodiment of the invention, the temperature is indirectly determined from the thermal expansion of the heater. This thermal expansion leads to a change in the electrical resistance. The electrical resistance is directly proportional to the specific electrical resistance, and inversely proportional to the length of the conductor through which the current flows. Further, the electrical resistance depends directly on the cross-section of that conductor. In direct current technology, the following relationship can be found between the resistance on one side and the specific resistance, the cross-section and the length of the conductor on the other:

$$R = ρ \frac{A}{L}$$

The induction of a current on the secondary side, causes a current to flow through the heater. The heater heats up its environment and is itself also heated up in this way. Because of the raised temperature, the heater expands and changes its resistance. This change in resistance can be measured on the secondary side, but preferably on the primary side. For a secondary-side measurement the resistance is preferably determined by an electronic system. An accordingly produced measurement signal is produced by the electronic system and transmitted contactlessly by the inventive method.

In an especially preferred embodiment of the invention, the temperature is measured indirectly via the impedance on the secondary side. Impedance is understood to mean the alternating current resistance. It can be calculated from the voltage drop at a consumer device and the current drawn. The strength of current I, which flows through a consumer, and the voltage drop U, depend first of all on its resistance:

$$I = \frac{U}{R}$$

On the other hand, the resistance can be determined by measuring the voltage and the current:

$$R = \frac{U}{I}$$

In alternating current technology, one uses the periodically changing variables U(t) and I(t) and determines the impedance, that is the alternating current resistance by:

$$\underline{Z} = \frac{U ( t )}{I ( t )}$$

Impedance is a vectorial variable which can easily be mapped as appropriate in a polar coordinate system. By measuring the periodically changing alternating voltage U(t) and the periodically changing current I(t), which has to change when there is a rise in temperature on the secondary side because the resistance changes, conclusions can be drawn as to the temperature. Because this method according to the invention concerns an indirect temperature measurement, a calibration of the system is preferably carried out. In this context it is best to correlate the measured impedance with a temperature measured by an external, in particular a very accurate, temperature measuring device. In this way, in a control procedure according to the invention, it is possible to draw conclusions as to the temperature by measuring the impedance. The induction coupling according to the invention therefore simultaneously transmits the measurement signal. This embodiment of the invention does not need its own measuring circuit.

In another preferred embodiment of the invention, the measurement signal is decoupled from the rotor to the stator via a capacitive coupling. The measurement signal is recorded by at least one sensor, in particular a thermal element. The signal is preferably appropriately pre-processed in an electronic system located in the sample holder. For that purpose the device comprises stator-side capacitor components and rotor-side capacitor components.

In another preferred embodiment of the invention, the measurement signal is transmitted from the rotor to the stator by a radiation measurement, in particular an infrared measurement. The measurement signal is received by at least one sensor, in particular a thermal element. The signal is preferably appropriately pre-processed in an electronic system located in the sample holder. An appropriate transmitter, in particular an infrared transmitter, is located on the rotor, and an appropriate receiver, in particular an infrared receiver, is located on the stator. In principle, electromagnetic rays in the wavelength range between 2000 nm and 1000 μm, preferably between 1500 nm and 1000 μm, more preferably between 1000 nm and 1000 μm, most preferably between 780 nm and 1000 μm, are used.

In another preferred embodiment of the invention, the transmission of the signal is achieved by radio. Appropriate radio transmitters and receivers are necessary for this purpose. The device therefore has stator-side receivers and rotor-side radio transmitters. In particular, the radio module on the rotor side must be operated using appropriate electronics and a constant voltage, or current. In general, the principle applies that the electronics are located in the rotor, in the stator, or a computer set up separately from the embodiment of the invention. The wavelength range is above the infrared wavelength. The wavelength is between 1 mm and 10 km, preferably between 1 cm and 1 km, more preferably between 1 dm and 100 m, most preferably between 1 dm and 50 m, most preferably of all, between 1 dm and 25 m.

### Control Arrangement

In another preferred embodiment of the invention, a control arrangement exists between the inductive coupling and the measuring system. The control arrangement continually determines the measured values, in particular the temperature or temperature variation, and regulates the temperature in dependence of the respective prescribed target value. PID controllers are used for preference. The PID controllers can be software and/or hardware PID controllers. Control is preferably implemented using a soft controller which is implemented on a PLC system. The initial control variable of this controller influences the amplitude of the heater's primary voltage.

In order to hold the transmitted power constant in accordance with a preferred embodiment of the invention, the rotational speed of the sample holder must be available as an input variable for adaptive control of the power circuit.

### Exchangeability

Different rotors can be swapped very quickly by means of an electromechanical decoupling of the rotor from the stator. It is possible for example, that the rotors have a shaft with a groove on the underside, into which the tappet of a drive shaft engages in order to transfer the momentum. Such constructions are easy to build and maintain. Due to the electromechanical decoupling of the rotor from the stator in accordance with the invention and dispensing with sliding contacts, the changeover can be achieved completely effortlessly, in particular even automatically by a robot.

The rotors in the embodiments of the invention are preferably individually calibrated. Once one of the rotors has been changed, the software must carry out a new calibration or at least load an old calibration. Automatic identification of the rotor, in particular with the aid of RFID chips, is a further proposed development of the invention. The rotor is inserted, automatically recognised, and the appropriate calibration programme is activated in the software being employed. This ensures an unambiguous allocation of the rotor to the correct calibration.

### Encapsulation

Since heating elements as well as elements for transmitting measurement signals are located inside one chamber, the embodiments of the invention have the advantage of fulfilling certain fire-protection requirements. The most important fire-protection requirements are:
sealing the stator against the rotor
flushing of the rotor with an inert gas under an overpressure
   Because flammable media are usually employed, it must also be ensured that measures protecting against explosions are complied with:
no hot surfaces—safe temperature limits
no sparking
no electrostatic charges

Further advantages, features, and details of the invention are revealed in the following description of preferred exemplary embodiment as well as by means of the drawings in which

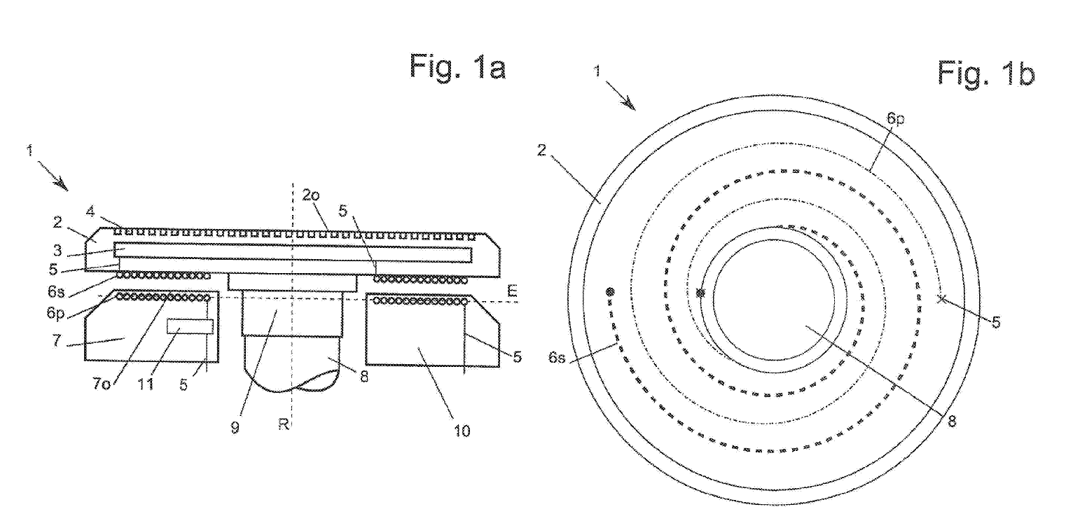

FIG. 1a shows a schematic, not-to-scale drawing of a cross-section through a part of a first embodiment of the invention,

FIG. 1b shows a schematic, not-to-scale top view of part of the first embodiment of the invention,

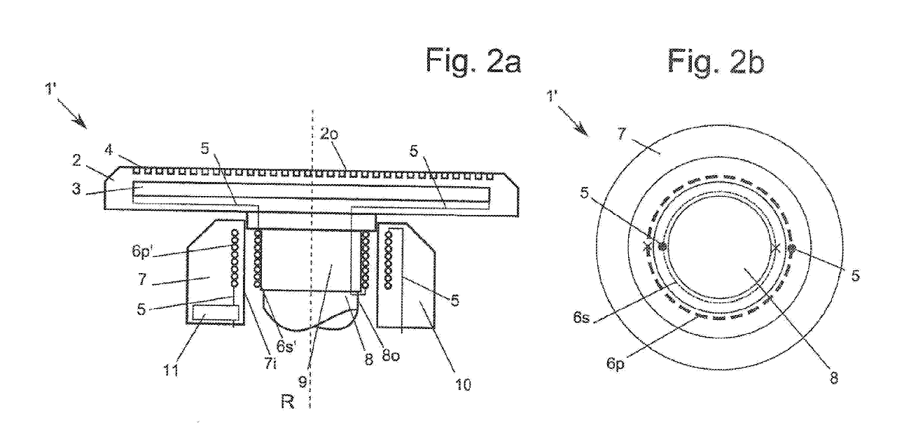

FIG. 2a shows a schematic, not-to-scale drawing of a cross-section through a part of a second embodiment of the invention,

FIG. 2b shows a schematic, not-to-scale top view of part of the second embodiment of the invention,

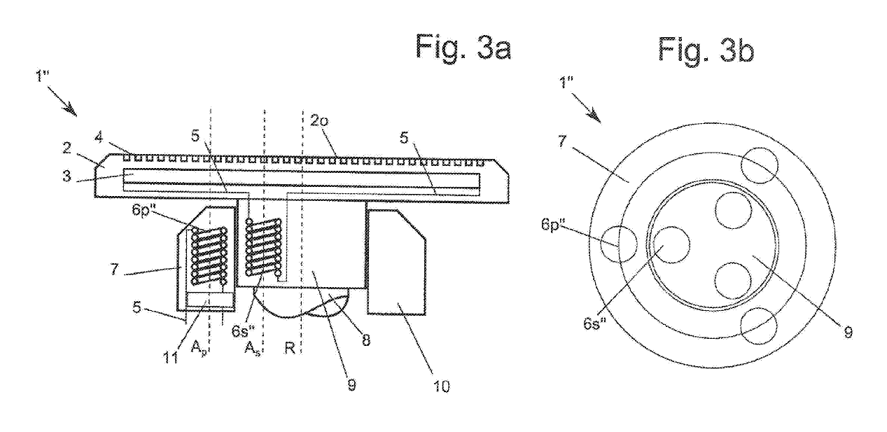

FIG. 3a shows a schematic, not-to-scale drawing of a cross-section through a part of a third embodiment of the invention,

FIG. 3b shows a schematic, not-to-scale top view of part of the third embodiment of the invention,

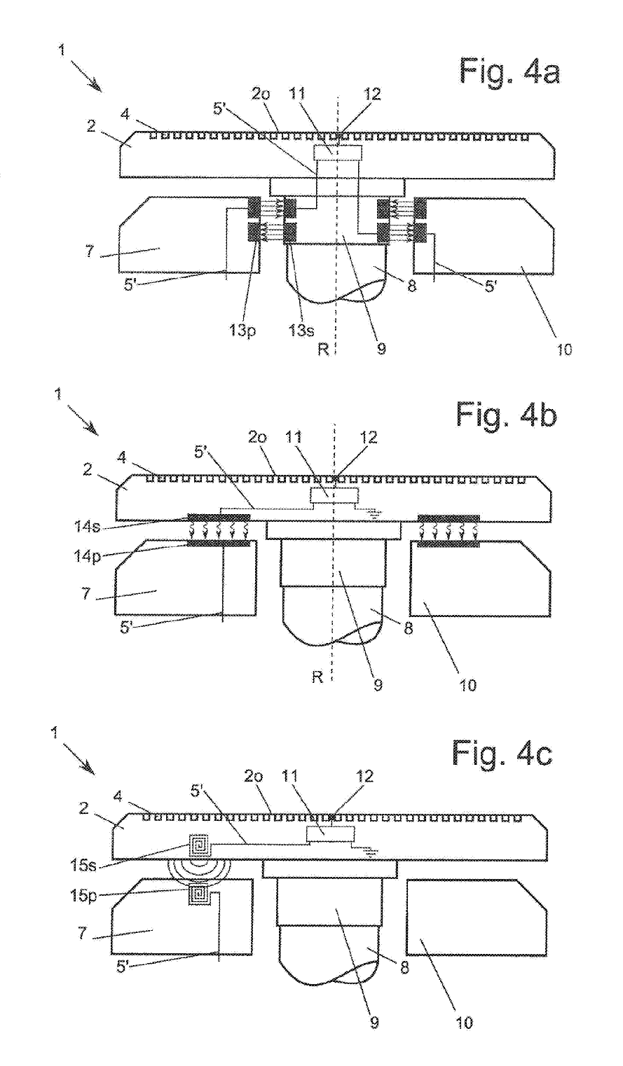

FIG. 4a shows a schematic, not-to-scale drawing of a cross-section through a part of another embodiment of the invention with capacitive measurement,

FIG. 4b shows a schematic, not-to-scale drawing of a cross-section through a part of another embodiment of the invention with infrared measurement,

FIG. 4c shows a schematic, not-to-scale drawing of a cross-section through a part of another embodiment of the invention with radio measurement,

FIG. 4d shows a schematic, not-to-scale drawing of a cross-section through a part of another embodiment of the invention with radiation measurement,

FIG. 4e shows a schematic, not-to-scale drawing of a cross-section through a part of another embodiment of the invention with radiation measurement.

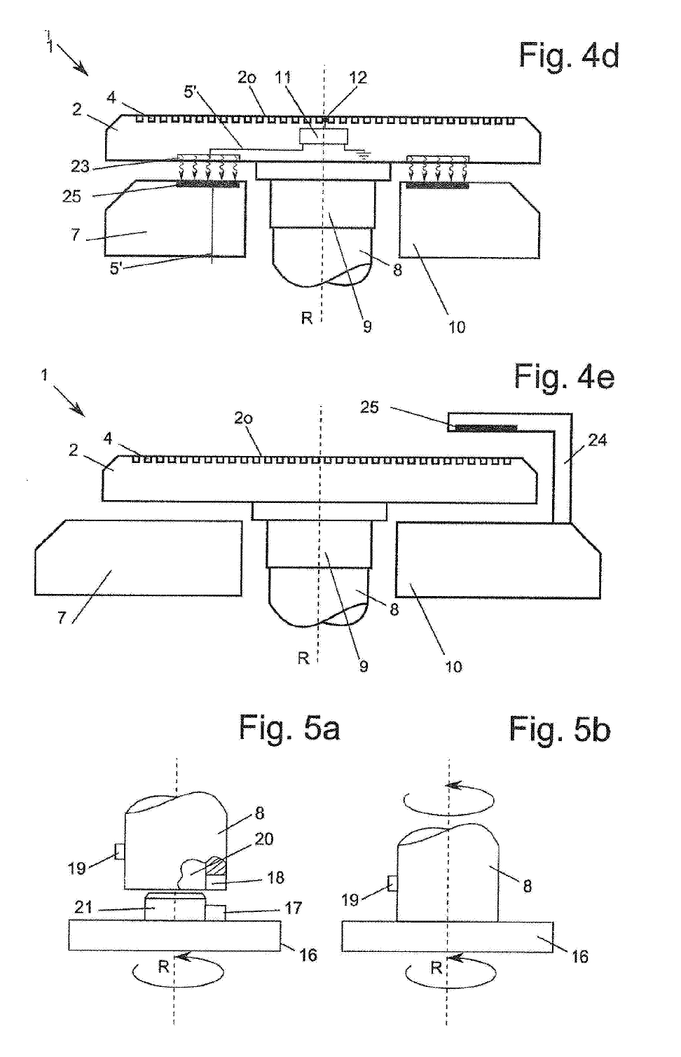

FIG. 5a shows a schematic, not-to-scale drawing of a cross-section through a part of another embodiment of the invention with a coupling before the coupling engages,

FIG. 5b shows a schematic, not-to-scale drawing of a cross-section through the coupling after the coupling engages,

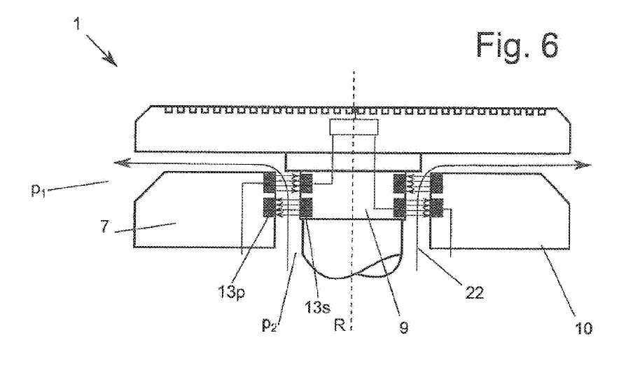

FIG. 6 shows another embodiment of the invention.

In the figures, identical components, or components with the same function are marked with the same reference symbols.

In the following FIGS. 1a to 3b, electronics 11, in particular for controlling a heater 3, may be present in the primary and/or secondary circuit(s). The heater 3 is preferably supplied with power exclusively via a voltage induced in a secondary winding 6s (also called a secondary coil 6s in the following), whilst control of the same by electronics 11 in a stator occurs exclusively on the primary side.

FIG. 1a shows a schematic, not-to-scale drawing of a cross-section through a first device 1 according to the invention. In particular the components necessary for transferring the electric power are represented, whilst the components for measuring a temperature are shown in FIGS. 4a to 4c.

The device 1 comprises a rotor 9 with a rotary shaft 8 (also called shaft 8 in the following) with a rotary axis R and a stator 10. A primary winding 6p (also called primary coil 6p in the following) is built into the stator 10. The primary winding 6p concerns, in particular a flat coil. The primary winding 6p may be installed on either a base surface 7o of the base 7, or as represented in the figure, in the base 7.

Current, in particular alternating current, flows through the primary winding 6p via wires 5. According to the invention, the alternating magnetic field produced by this in the secondary winding 6s, induces a voltage. The induced voltage allows the production of a current, which flows through the heater 3 and allows the heating up of the sample holder 2 with a sample holder surface 20 and fixing elements 4, but in particular a fixed substrate.

For the sake of completeness it is noted that a flat coil, in particular the primary winding 6p, is not radially symmetrical in relation to an axis A, which normally stands on a plane E, in which the flat coil is located. Therefore a static magnetic field produced by a direct current will also not be radially symmetrical. In accordance with Faraday's law of induction, a voltage must therefore be induced in a conductor loop rotating in the non-symmetrical magnetic field, in particular the rotating secondary winding 6s, which is also designed as a flat coil. Nevertheless, an inductive coupling through an alternating magnetic field caused by an alternating current is to be preferred for control-technology and other physical reasons. In particular, induced voltage is always directly proportional to periodical variation of the magnetic flux. The higher the frequency of the applied alternating current, the faster is the variation in the magnetic flux and the higher is the induced voltage.

FIG. 1b shows a schematic, not-to-scale top view of the device 1 with the primary coil 6p and the secondary coil 6s. Both coils 6p, 6s are constructed as flat coils, in particular spiral coils, more preferably Archimedean coils. The Archimedean spirals comply with the mathematical equation:

r(ϕ)=a*ϕ

wherein r(ϕ) is the radius at the angle position ϕ and a is a constant. The smaller the constant a, the smaller the distance between the spiral arms. The distance between the two arms of an Archimedean spiral along a ray radiating out from the coordinate origin always equals 2πa. For the sake of clarity the two flat coils 6p, 6s are depicted in FIG. 1b with a bigger constant a than in FIG. 1a. FIG. 2a shows a schematic, not-to-scale drawing of a cross-section through a second device 1′ according to the invention.

FIG. 2b depicts, in particular, the components necessary for transferring the electrical power, whilst the components for measuring temperature are shown in FIGS. 4a to 4c.

The device 1′ according to the invention, comprises a rotor 9 and a stator 10. There is a primary winding 6p′ and a secondary winding 6s′ which are cylinder coils arranged concentrically to each other. The primary winding 6p′ may be built into either an inner base surface 7i of the base 7, or, as depicted in FIG. 2a, the inside of the base 7. An alternating current passes through the primary winding 6p′ via the wires 5. The secondary winding 6s′ may be located, as depicted in FIG. 2a on a shaft surface 8o or in the shaft 8.

FIG. 2b shows a schematic, not-to-scale top view of the device 1′ with the primary winding 6p′ and the secondary winding 6s′. Both coils 6p′, 6s′ are realised as cylinder coils. The concentric position of the primary coil 6p′ and the secondary coil 6s′ in relation to the rotary axis R is visible.

FIG. 3a shows a schematic, not-to-scale drawing of a cross-section through a third device 1″ according to the invention.

It depicts, in particular, the components necessary for transferring the electrical power, whilst the components for measuring temperature are shown in FIGS. 4a to 4c.

In the device 1″ according to the invention, there is at least one primary winding 6p″ in the stator 10, and at least one secondary winding 6s″ in the rotor 9.

A symmetry axis Ap of the primary winding 6p″ and a symmetry axis As of the secondary winding 6s″ are not arranged congruently. They are arranged acentrically in relation to the rotary axis R. In particular, several of such primary windings 6p″ may be positioned in the stator 10 and/or several secondary windings 6s″ in the rotor 9. The primary winding 6p″ and/or the secondary winding 6s″ may be positioned symmetrically or asymmetrically in the stator 10, or rotor 9. The symmetry axes Ap and/or As may be at any angle to the rotary axis R. However, the symmetry axes Ap and/or As are preferably parallel to the rotary axis R.

FIG. 3b shows a schematic, not-to-scale sectional view in which three primary windings 6p″ arranged at an angular distance of 120° to each other in the stator 10 and three secondary windings 6s″ arranged at an angular distance of 120° to each other in the rotor 9, are visible.

FIGS. 1a to 3a, at the same time, also show all the components necessary for constructing a first measurement and data transmission device according to the invention (also called a measuring system in the following) in which the inductive coupling can be used, for example, to determine the temperature of the heater 3 by using an impedance measurement. It will be clear to any expert in this field, that where there is an increase in the temperature of the heater, the secondary-side impedance changes. However, due to the inductive coupling, the primary-side impedance also changes, which can easily be determined by measuring the voltage and the current as already described further in the above text. Thus, the primary-side impedance measurement offers the possibility of determining the secondary-side temperature. The primary-side impedance is preferably calibrated using the measured secondary-side temperature, or temperature variation. In this way, for each impedance value, or impedance variation, a corresponding temperature, or temperature variation, is obtained.

FIG. 4a shows a schematic, not-to-scale drawing of a cross-section through another device 1 according to the invention, in which a second measuring system in accordance with the invention is depicted. For the sake of clarity, the components for transferring power in accordance with FIGS. 1a to 3b are not shown.

The sample holder 2 contains electronics 11 for activating at least one thermal element 12. In accordance with the invention, several thermal elements 12 may be present. The thermal element 12 is preferably attached to the sample holder surface 2o of the sample holder 2 in order to be able to measure the temperature of a fixed substrate. In special embodiments the temperature element 12 can also be located in the sample holder 2. A combination of thermal elements 12 which are installed in the sample holder 2 and on the sample holder surface 2o, is also possible.

The electronics 11 are part of an electrical circuit closed via primary-side capacitor parts 13p and secondary-side capacitor parts 13s and wires 5′. The primary-side capacitor parts 13p and the secondary-side capacitor parts 13s are preferably completely closed rings. It would also be feasible to use primary-side ring segments 13p and/or secondary-side ring segments 13s. If the primary-side capacitor parts 13p and the secondary-side capacitor parts 13s are ring segments, the electrical circuit will only ever be briefly closed after a full rotation.

FIG. 4b shows a schematic, not-to-scale drawing of a cross-section through another device 1 according to the invention in which a third measuring system in accordance with the invention is depicted. For the sake of clarity, the components for transferring power in accordance with FIGS. 1a to 3b are not shown.

The sample holder 2 contains electronics 11 for controlling at least one thermal element 12. In accordance with the invention, several thermal elements 12 may be present. The thermal element 12 is preferably attached to the sample holder surface 2o of the sample holder 2 in order to be able to measure the temperature of a fixed substrate. In special embodiments the temperature element 12 can also be located in the sample holder 2. A combination of thermal elements 12 which are installed in the sample holder 2 and on the sample holder surface 2o, is also possible.

The electronics 11 are part of an electrical circuit closed via primary-side infrared receivers 14p and secondary-side infrared transmitters 14s. The infrared receivers 14p and infrared transmitters 14s constitute an opto-coupler. The infrared receivers 14p and infrared transmitters 14s are preferably ring-shaped.

FIG. 4c shows a schematic, not-to-scale drawing of a cross-section through another device 1 according to the invention in which a fourth measuring system in accordance with the invention is depicted. For the sake of clarity, the components for transferring power in accordance with FIGS. 1a to 3b are not shown.

The sample holder 2 contains electronics 11 for activating at least one thermal element 12. In accordance with the invention, several thermal elements 12 may be present. The thermal element 12 is preferably attached to the sample holder surface 2o of the sample holder 2 in order to be able to measure the temperature of a fixed substrate. In special embodiments the temperature element 12 can also be located in the sample holder 2. A combination of thermal elements 12 which are installed in the sample holder 2 and on the sample holder surface 2o, is also possible.

The electronics 11 are part of an electrical circuit closed via a primary-side radio receiver 15p and a secondary-side radio transmitter 15s. The secondary-side radio transmitted 15p does not necessarily have to be located in the stator 10, but may also be located anywhere within range of the radio transmitter 15s, in particular in a computer.

FIG. 4d shows a schematic, not-to-scale drawing of a cross-section through another device 1 according to the invention in which a fifth measuring system in accordance with the invention is depicted. For the sake of clarity, the components for transferring power in accordance with FIGS. 1a to 3b are not shown. The measuring system according to the invention allows the determination of the temperature of the sample holder 2 using radiant power. According to embodiments of the invention already mentioned, the underside and/or the rim of the substrate holder 2 is thermally insulated. According to the present embodiment of the invention, an infrared transparent window 23 is located on the underside of the substrate holder 2, via which radiation, in particular infrared radiation, can exit the substrate holder 2. A detector 25 can measure the radiation emitted in this way and the radiation curve, or radiant power can be used to calculate the temperature of the sample holder 2. The detector 25 is preferably an infrared detector. However, detectors which can measure radiant power over a wider range of frequencies than infrared are also feasible.

FIG. 4e shows a schematic, not-to-scale drawing of a cross-section through another device 1 according to the invention in which a sixth measuring system in accordance with the invention is depicted. For the sake of clarity, the components for transferring power in accordance with FIGS. 1a to 3b are not shown. The measuring system according to the invention has a detector arm 24, on which a detector 25 is mounted, which can measure the surface of the sample holder 2, in particular however, the surface of a substrate (not shown) lying on the surface. The detector 25 is preferably an infrared detector. However, detectors which can measure radiant power over a wider range of frequencies than infrared are also feasible.

FIG. 5a shows the lower part of a rotary shaft 8 of a rotor 9 with a bore 20 and a groove 18 above a drive shaft 16 with tappets 17 and pins 21 prior to coupling. An identification chip 19, in particular an RIFD chip, may be located on the rim of the shaft 8 which allows unambiguous and, in particular, fully automated identification of the rotor 9. The identification chip 19 may also be installed in the shaft 8, or in any other part of the rotor 9. The bore 20 of the shaft 8 sits on the pin 21 of a drive shaft 16 in such a way that the tappet 17 is enclosed by the groove 18.

FIG. 5b shows the lower part of the shaft 8 when coupled to the drive shaft 16. Both FIGS. 5a and 5b only show a very simplified exemplary coupling system which can be substituted by generically similar coupling systems. However, the coupling systems are preferably always designed so that a fully automated coupling of the rotor 9 via the shaft 8 with the drive shaft 16, is possible, in particular by a robot.

FIG. 6 shows another device according to the invention in which a gas flow, in particular an inert gas flow, flushes the rotor 9. In this way all of the externally placed electric components, for example the primary-side capacitor part 13p and the secondary-side capacitor part 13s, are also flushed and therefore protected.

By flushing such externally placed current-carrying or charge-carrying components with an inert gas 22, sparking is again reduced by a multiple. However, the main reason for using such an inert gas 22 is primarily that an overpressure is built up between the rotor 9 and the stator 10, which is greater than the ambient pressure p1.

In this way the ingress of potentially flammable fluids, vapours or gases between the rotor 9 and the stator 10 is made more difficult, or even completely prevented.

### LIST OF REFERENCE SYMBOLS

1,1′,1″ Device
2 Substrate holder
2o Substrate holder surface
3 heater
4 fixing elements
5,5′ cables/wires
6p,6p′,6p″ primary windings
6s,6s′,6s″ secondary windings
7 base
7o base surface
7i base inner surface
8 rotary shaft
8o shaft surface
9 rotor
10 stator
11 electronics
12 thermal element
13p primary-side capacitor part
13s secondary-side capacitor part
14p primary-side infrared receiver
14s secondary-side infrared transmitter
15p primary-side radio receiver
15s secondary-side radio transmitter
16 drive shaft
17 tappet
18 groove
19 identification chip
20 bore
21 pins
22 gas flow
23 infrared window
24 detector arm
25 detector
Ap primary-side symmetry axis
As secondary-side symmetry axis
R rotary axis
E plane
p1,p2 pressure

1. A device for holding, rotating, heating and/or cooling a substrate, said device comprising:
a rotor having:
at least one secondary winding,
a substrate holder with a substrate holder surface and fixing elements for fixing the substrate,
a rotary shaft for rotating the substrate holder around a rotary axis,
at least one electric heater for heating and/or a cooler for cooling the substrate holder surface; and
a stator having:
at least one primary winding,
a ring-shaped base, wherein the rotary shaft of the rotor is arranged at least partially inside the base;
wherein a current and/or a voltage is induced in the at least one secondary winding by the at least one primary winding, and
wherein the current and/or voltage induced in the at least one secondary winding powers the at least one heater and/or cooler to heat and/or cool the substrate holder surface.

2. The device according to claim 1, wherein the at least one primary winding is arranged on a base surface.

3. The device according to claim 1, wherein the at least one primary winding is arranged inside the base.

4. The device according to claim 1, wherein the at least one primary winding and the at least one secondary winding are configured as flat coils.

5. The device according to claim 4, wherein the at least one primary winding and the at least one secondary winding are arranged parallel to one another.

6. The device according to claim 4, wherein the at least one primary winding and the at least one secondary winding are arranged in and/or parallel to a plane that is arranged at right angles to the rotary axis.

7. The device according to claim 4, wherein the at least one primary winding is arranged on a base surface of the base, facing the substrate holder.

8. The device according to claim 4, wherein the at least one secondary winding is arranged on a reverse side of the substrate holder, facing the base.

9. The device according to claim 1, wherein the at least one primary winding and the at least one secondary winding are configured as cylinder coils.

10. The device according to claim 9, wherein the at least one primary winding and the at least one secondary winding are arranged concentrically in relation to the rotary axis.

11. The device according to claim 9, wherein the at least one primary winding is arranged on an inner base surface of the base facing the rotary shaft and the at least one secondary winding is arranged on a shaft surface of the rotary shaft facing the inner base surface.

12. The device according to claim 9, wherein the at least one primary winding and the at least one secondary winding are arranged acentrically in relation to the rotary axis.

13. The device according to claim 9, wherein at least two primary windings are arranged inside the base and at least two secondary windings are arranged inside the rotary shaft.

14. The device according to claim 13, wherein the at least two primary windings and the at least two secondary winding are arranged at an equal angular distance around the rotary axis.

15. The device according to claim 1, wherein the device further comprises:
a measuring device for measuring the temperature of the heater, the substrate holder, the substrate holder surface and/or the substrate, and
a device for transmitting the temperature measurements for the heater, the substrate holder, the substrate holder surface and/or the substrate from the rotor to the stator via the inductive coupling between the at least one primary winding and the at least one secondary winding.

16. The device according to claim 1, wherein the rotor has an identification chip for identification of the rotor, wherein the identification chip is located on the rim of the rotary shaft.

17. The device according to claim 1, wherein the device further comprises a flushing agent for flushing the rotor using a gas flow.

18. A method for holding, rotating and heating and/or cooling a substrate, said method comprising:
holding the substrate using a rotor comprised of a substrate holder with a substrate holder surface and fixing elements for fixing the substrate, and
inducing a current in at least one secondary winding of the rotor using at least one current-carrying primary winding of a stator,
wherein the current induced in the at least one secondary winding powers at least one heater and/or cooler so that the substrate holder surface, and thereby the substrate, are heated and/or cooled.

19. The method according to claim 18, wherein the rotor is flushed by a gas flow wherein a primary-side capacitor component and a secondary-side capacitor component are flushed, and wherein an overpressure is built up between the rotor and the stator, which is greater than an ambient pressure.
